(19) United States
(12) Patent Application Publication
(10) Pub. No.: US 2005/0087126 A1
(43) Pub. Date: Apr. 28, 2005

(54) Non-contact orbit control system for Czochralski crystal growth

(76) Inventor: Daniel F. Pratt, Battle Ground, WA (US)

Correspondence Address: SEH AMERICA, INC., M/S 58-1-921, 4111 N.E. 112TH AVE., VANCOUVER, WA, 98682, US

(21) Appl. No.: 10/692,405

(22) Filed: Oct. 22, 2003

(51) Int. Cl. C30B 35/00; C30B 15/00; C30B 21/06; C30B 27/02; C30B 28/10; C30B 30/04

(52) U.S. Cl. 117/217; 117/13; 117/218

(57) ABSTRACT

A Czochralski single crystal pulling apparatus having a one or more flow nozzles used to reduce or eliminate unwanted orbital motion during crystal growth. A portion of the purge gas supplied to the crystal puller is diverted to the flow nozzles, which direct purge gas flow on the growing crystal in a direction that counteracts the orbital force. Mass flow controllers and/or valves are actuated by a controller such that flow is only directed by any flow nozzle when the crystal is in a perigree interval relative to that nozzle, with the proper amount of purge gas directed such that orbit can be significantly reduced or eliminated.

### FIELD OF THE INVENTION

This invention relates generally to Czochralski type crystal pulling machines, and more specifically to a method and apparatus for controlling pendular motion of the crystal during growth.

### BACKGROUND OF THE INVENTION

Semiconductors used in the electronics industry are typically manufactured from monocrystalline ingots, such as silicon ingots, grown by the so-called Czochralski (CZ) process. In the CZ process, a charge material such a polysilicon chunks is loaded in a crucible, which is placed inside a crystal growing machine. The charge material is then heated to bring it to a molten state and allowed to thermally stabilize throughout the molten mass. A monocrystalline seed containing the crystallographic properties desired of the ingot to be grown is attached to a cable and lowered down to be dipped into the molten mass. The seed is then slowly extracted from the melt, wherein material from the melt attaches to the bottom of the seed, matching the crystallographic properties of the seed, such that an ingot is “grown”. Under ideal conditions, the ingot grown can achieve diameters of up to 300 mm or larger. An inert purge gas, such as argon, is passed downward from the top of the machine over the melt and growing crystal, and vented out the bottom of the machine. The vent gas is used to remove reactive SiC gases created from the interaction of the molten silicon with the quartz crucible, as well as to provide a means for cooling the growing crystal and meet thermal gradient requirements. Typically the seed is rotated relative to the melt, either by rotating the seed and seed cable, the crucible containing the melt, or more often rotating both. This rotation helps improve stability of oxygen concentration and dopant concentration radially through the growing crystal, as well has help maintain the desired cylindrical shape of the growing ingot.

Under ideal conditions, the crystal being grown through an imaginary axial axis running directly downward from the point of entry of the cable or wire in the top of the machine through the center of the crystal such that the only motion of the crystal is the growth directly upward and the rotation of the crystal around its axial axis. Due to the rotation of the crucible and the growing crystal however, a phenomenon known as orbit may occur, wherein the growing ingot swings in a pendular motion while the crystal is growing. Since the crystal is growing at the interface of the ingot and the molten material, and since the ingot and molten material are rotating in opposite directions, the added angular forces added from orbit cause the ingot to grow in a non-linear fashion similar to the shape of a cork screw. Any non-linear shape is undesirable, as it reduces the amount of usable ingot and increases handling costs associated with trying to salvage sections of usable ingot.

Similarly, when orbit occurs the pendular motion inhibits accurate diameter measurements from being made, such that an ingot may be grown to a diameter larger than desired, thereby lowering productivity and costs associated with manufacturing. If a crystal ingot is grown to a diameter smaller than desired, that entire section of crystal may be discarded as scrap, again negatively impacting productivity and yields.

Attempts have been made to prevent orbit from occurring, with limited success. For example, U.S. Pat. No. 5,089,239 teaches one or more mechanical dampening devices that surround the cable at a specified location about midway between the top of the machine and the molten mass. As orbit occurs, the cable begins to oscillate in a pendular motion and comes in contact with the mechanical dampening device. The theory of this device being contact with the cable at that location would shorten the free length of the wire, and significantly increase the natural oscillation frequency, thereby reducing orbit.

Similarly, U.S. Pat. No. 5,582,642 provides an apparatus, this time near the top of the machine, with a guide capable of being moved horizontally in at least two non-collinear directions, and a sensor, attached to a controller, to determine where the cable is touching. The guide is moved by an actuator to dampen the oscillation of the cable.

There are significant disadvantages to these methods, however. Primarily, each of the known methods requires physical contact of the guide with the wire. Since the wire is both rotating and being raised through the guide, friction occurs. This friction causes wear on both the cable and the guide, eventually causing particles to shed from them. These particles can then make their way into the melt and cause contamination in the melt and the resultant crystal grown therefrom.

### SUMMARY OF THE INVENTION

In order to overcome the drawbacks and limitations of a physical guide to limit or inhibit orbit, the present invention provides an apparatus and method to prevent or limit orbit by controlled purge gas flow. Utilizing a diameter control system for crystal growth, or another dedicated detector, the characteristics of the orbiting crystal can be determined. A controller then will actuate one or more valves to supply purge gas directed on the crystal to counter the orbit. By utilizing purge gas and valves to counteract orbit, sources of contamination and wear can be eliminated.

### BRIEF DESCRIPTION OF THE DRAWINGS

FIG. 1 is a partial sectional view of a crystal growing apparatus containing purge gas flow nozzles.

FIG. 2 is a block diagram depicting a crystal growing apparatus purge gas supply and controller.

FIG. 3 is a top view of purge gas flow nozzles.

### DETAILED DESCRIPTION OF THE INVENTION

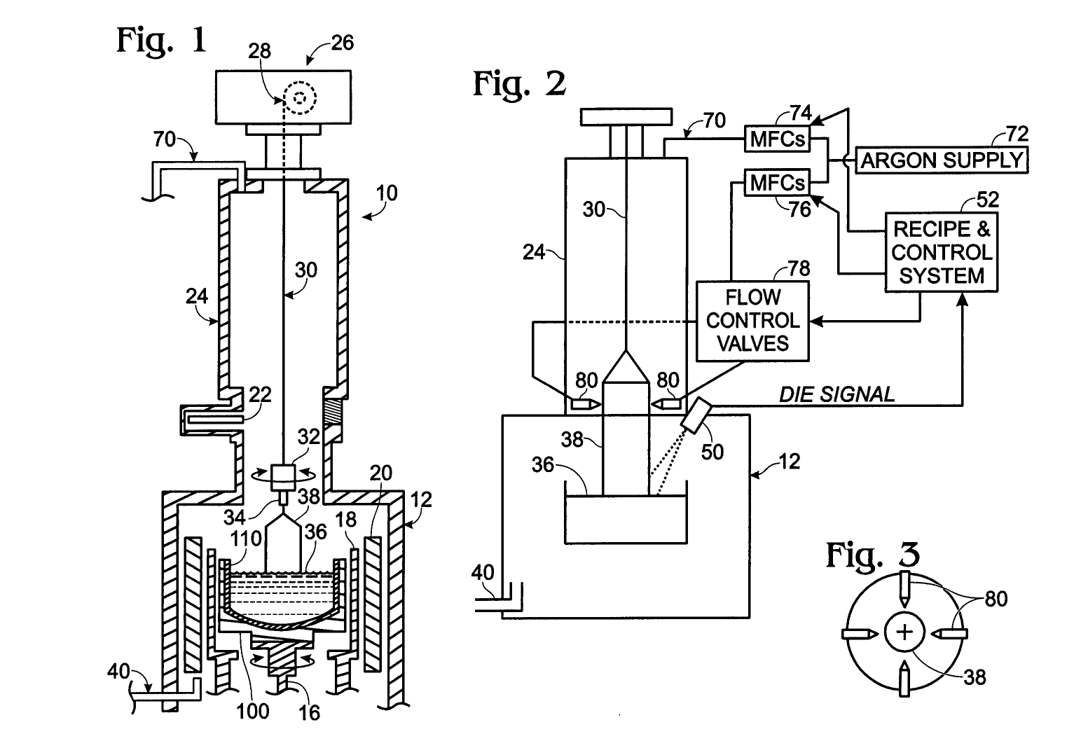

Turning now to FIG. 1, a crystal growing apparatus 10 includes a bottom chamber 12. The bottom chamber 12 houses a quartz crucible 110, which is supported by a susceptor 100. The susceptor 100 is in turn supported by a vertically moveable and rotatable shaft assembly 16. A cylindrical heater 18 made of, for example, graphite is disposed around the susceptor 100, which in turn is surrounded by an insulating cylinder 20. The bottom chamber 12 also has a conduit 40 for evacuating air during start up, and process gas during crystal pulling operations utilizing a vacuum pump (not shown).

A top chamber 24 is disposed above the bottom chamber 12 while an isolation valve 22 is disposed there between. The top chamber 24 provides a space for accommodating a grown crystal. The isolation valve 22 functions to allow a vacuum tight separation between the top chamber 24 and the bottom chamber 12 thus enabling a grown crystal to be removed from the top chamber 24 without losing vacuum or temperature in the bottom chamber 12. The top chamber 24 has a conduit 70 that goes to a vacuum pump (not shown) that allows the top chamber to be evacuation of air and/or purge gases, so it may be rejoined with the bottom chamber 12. When the isolation valve 22 is opened, a purge gas such as argon is introduced through conduit 70, flowed through the entire growing apparatus 10, and exited through conduit 40.

A winding mechanism 26 is disposed above the top chamber 24, and includes a winding drum 28 within the winding mechanism 26. The winding mechanism 26 is rotatable around a vertical axis with respect to the top chamber 24. A wire 30 is wound onto the winding drum 28, and extends downward. A seed chuck 32 for holding a crystal seed 34 is attached to the lower end of wire 30.

When a single crystal is to be grown in the crystal growing apparatus 10, the isolation valve 22 is in an open position so as to allow the seed 34 to be lowered into the bottom chamber 12. Both the bottom chamber 12 and the top chamber 24 are evacuated and purged of air, and an inert gas is then flowed through the apparatus for the remainder of the growing process. A charge material, such as silicon, is placed in the crucible 110, and heated by the heater 18, thereby making a molten material 36.

The seed crystal 34 is lowered by winding drum 28 until the end of the seed crystal 34 is lowered into the molten material 36. After allowing the seed crystal 34 to reach temperature equilibrium with molten material 36, the winding drum 28 slowly begins to wind up the wire 30, thus enabling a crystal 38 to be pulled or grown. During the growing operation, the winding mechanism 26 and thus the seed crystal 34 are rotating in the opposite direction of the shaft assembly 16.

As shown in FIG. 2, a crystal diameter measuring device 50 is employed to measure the diameter of the growing crystal 38. The diameter measuring device 50 may be one or more CCD cameras, a laser system, or other device known in the industry. It should be noted, however, that another sensing device may be used instead of or in combination with the diameter measuring device to detect orbit, including a proximity sensor that detects the wire 30 when it is swinging in an orbital motion. In operation, the measuring device 50 will monitor an area in the proximity of where the growing crystal 38 intersects the molten material 36. A signal from the measuring device 50 is sent to a controller 52. Based on the signal sent, the controller 52 may adjust various growth parameters or combinations of growth parameters such as the power supplied by the heater 18 to increase or decrease the temperature of the molten material 36, or changing the rate at which the winding drum 28 winds the wire 30 and pulls the crystal 38. One reason these parameters may be changed is to control the proper diameter of the crystal 38.

From the signal sent from the measuring device 50 to the controller 52, a mathematical representation of orbit, such as a sine wave curve, can also be generated. Information can be calculated such as the frequency or period of the motion and the magnitude of displacement. The controller 52 then calculates and produces a cancellation signal appropriate to control and eliminate or reduce orbit through gas flow dynamics. A portion of the purge gas is then taken from the purge gas supply 72 and diverted from conduit 70 to a mass flow controller 76, through flow control valves 78, and out one or more flow nozzles 80. FIG. 2 shows the flow nozzles 80 located in the bottom of the top chamber 24, but the location is not limited to this position. Flow nozzles 80 could be placed in the top of the bottom chamber 12, or higher in the top chamber 24. Alternatively, there could be a plurality of flow nozzles 80 placed vertically in the bottom and top chambers 12 and 24 respectively. In this case, the flow nozzles could be utilized to flow purge gas on any of the wire 30, the seed chuck 32, the neck, shoulder, or body sections of the growing crystal 38, individually or in any combination, as the crystal gains length.

As shown in FIG. 3, the one or more flow nozzles 80 are located circumferentially around the growing crystal 38 and aimed inward at the crystal 38. The flow nozzles 80 may be directed radially perpendicular to the crystal 38, skewed, or angled axially such that the purge gas strikes the surface of the crystal 38 at an oblique angle. When more than one flow nozzle 80 is employed, it may be preferred to space them equidistant from one another. The controller 52 would control the flow nozzles 80 such that as the orbiting crystal approaches a position of a particular nozzle where the crystal 38 begins to move toward that particular nozzle, that particular nozzle would be activated and purge gas would flow through the nozzle and contact the orbiting crystal to exhibit a force on the crystal radially inward to guide the crystal back toward the desired axial center. Gas flow would stop, or be reduced, at some predetermined time before or up to the crystal 38 reaching the perigree position for that particular nozzle. Purge gas would flow during a perigree interval, defined as an angular amount about the absolute perigree. For example, the controller 52 could allow purge gas flow from 180 angular degrees before the absolute perigree position to five angular degrees before the absolute perigree position to form a perigree interval. As the orbiting crystal continues its orbital path, each nozzle would in turn be activated at the appropriate time to counteract the orbital forces, thereby reducing or eliminating orbit. The resultant crystal grown under such conditions would approach idyllic then, with the center of gravity for the crystal being grown running through the axial center of the crystal and experiencing little or no orbit. Since the controller 52 is receiving continuous feedback on the orbit of the crystal, gas flow rates through the nozzles 80 may be increased or decreased depending on factors such as the magnitude of the orbit displacement, the diameter and mass of the growing crystal 38, gas dynamics, and viscosity of the molten material 36, the relative position of the nozzles 80 to the wire 30, seed chuck 32, and growing crystal 38. It should be understood that several configurations can accomplish the intent of the invention, such as one mass flow controller 76 with multiple control valves 78, one control valve 78 with many mass flow controllers 76, only the use of one or more mass flow controllers 76, or only the use of one or more control valves 78. In an alternative embodiment a constant flow of gas could be supplied to all nozzles, with each individual nozzle experiencing an increased gas flow during the perigree interval.

Although the invention has been described with reference to specific embodiments, other embodiments of the present invention will be apparent to those skilled in the art from a consideration of this specification or practice of the invention disclosed herein. It is intended that the written description be considered in all aspects only as illustrative and not restrictive. The scope of the invention is, therefore, indicated by the appended claims rather than by the foregoing description. All changes that come within the meaning and range of the equivalence of the claims are to be embraced within their scope.

1. An apparatus for reducing orbital motion during Czochralski crystal growth in a crystal pulling machine comprising:
a bottom chamber;
a crucible within the bottom chamber, the crucible rotatable around an axial axis and containing a molten material;
a top chamber above the bottom chamber;
a winding drum mounted on the top chamber, the winding drum rotatable around the axial axis;
a flexible member wound around the winding drum and extending downward along the axial axis into the pull chambers; the flexible member supporting and pulling a crystal from the molten material;
a sensor to detect orbital motion; and
at least one flow nozzle for directing a purge gas onto at least one of the flexible member and the crystal.

2. The apparatus of claim 1, wherein the sensor to detect orbital motion is a diameter measurement device.

3. The apparatus of claim 2, wherein the diameter measurement device includes at least one CCD camera.

4. The apparatus of claim 2, wherein the diameter measurement device includes a laser.

5. The apparatus of claim 1, wherein the sensor to detect orbital motion is a proximity sensor.

6. The apparatus of claim 1, wherein the flexible member is a wire.

7. The apparatus of claim 1, wherein the flexible member is a cable.

8. The apparatus of claim 1, wherein the at least one flow nozzle directs the purge gas radially inward toward the axial axis.

9. The apparatus of claim 8, wherein the flow nozzle directs the purge gas radially inward toward, and perpendicular to, the axial axis.

10. The apparatus of claim 8, wherein the flow nozzle directs the purge gas radially inward toward the axial axis at an oblique angle to the axial axis.

11. An apparatus for reducing orbital motion during Czochralski crystal growth in a crystal pulling machine comprising:
a bottom chamber;
a crucible within the bottom chamber, the crucible rotatable around an axial axis and containing a molten material;
a top chamber above the bottom chamber;
a winding drum mounted on the top chamber, the winding drum rotatable around the axial axis;
a flexible member wound around the winding drum and extending downward along the axial axis into the pull chambers; the flexible member supporting and pulling a crystal from the molten material;
a diameter measurement system to measure the diameter of the crystal and to detect orbit; and
at least one flow nozzle for directing a purge gas onto the crystal.

12. The apparatus of claim 11, wherein the diameter measurement system includes a controller for controlling flow of the purge gas to the at least one flow nozzle.

13. The apparatus of claim 12, wherein the controller operates at least one mass flow controller to control the volume of purge gas supplied to the at least one flow nozzle.

14. The apparatus of claim 12, wherein controller operates at least one control valve to open and close flow of the purge gas to each of the at least one flow nozzle.

15. The apparatus of claim 12, wherein purge gas is supplied to the at least one flow nozzle only when an orbiting crystal is in a perigree interval position to a flow nozzle.

16. The apparatus of claim 11, wherein a plurality of flow nozzles radially surround the crystal.

17. The apparatus of claim 11, wherein a plurality of flow nozzles are spaced vertically in the pulling machine.

18. The apparatus of claim 11, wherein the at least one flow nozzle directs the purge gas radially inward toward the axial axis.

19. The apparatus of claim 18, wherein the flow nozzle directs the purge gas in a flow perpendicular to the axial axis.

20. The apparatus of claim 18, wherein the flow nozzle directs the purge gas in a flow at an oblique angle to the axial axis.

21. The apparatus of claim 11, wherein the diameter measurement system includes a CCD camera.

22. The apparatus of claim 11, wherein the diameter measurement system includes a laser.

23. An apparatus for reducing orbital motion during Czochralski crystal growth in a crystal pulling machine comprising:
a bottom chamber;
a crucible within the bottom chamber, the crucible rotatable around an axial axis and containing a molten material;
a top chamber above the bottom chamber;
a winding drum mounted on the top chamber, the winding drum rotatable around the axial axis;
a flexible member wound around the winding drum and extending downward along the axial axis into the pull chambers; the flexible member supporting and pulling a crystal from the molten material;
a sensor to detect orbital motion;
a purge gas inlet in the top chamber for directing a purge gas downward through the pulling machine; and
at least one flow nozzle for directing a purge gas onto the crystal.

24. The apparatus of claim 23, wherein the sensor to detect orbital motion includes a controller for controlling flow of the purge gas to the at least one flow nozzle.

25. The apparatus of claim 24, wherein the controller operates at least one mass flow controller to control the volume of purge gas supplied to the at least one flow nozzle.

26. The apparatus of claim 24, wherein controller operates at least one control valve to open and close flow of the purge gas to each of the at least one flow nozzle.

27. The apparatus of claim 24, wherein purge gas is supplied to the at least one flow nozzle only when an orbiting crystal is in a perigree interval position to a flow nozzle.

28. The apparatus of claim 23, wherein a plurality of flow nozzles radially surround the axial axis and direct flow toward the axial axis.

29. The apparatus of claim 23, wherein a plurality of flow nozzles are spaced vertically in the crystal pulling machine.

30. The apparatus of claim 23, wherein the at least one flow nozzle directs the purge gas radially inward toward the axial axis.

31. The apparatus of claim 30, wherein the flow nozzle directs the purge gas radially inward toward the axial axis in a flow perpendicular to the axial axis.

32. The apparatus of claim 30, wherein the at least one flow nozzle directs the purge gas radially inward toward the axial axis at an oblique angle to the axial axis.

33. The apparatus of claim 23, wherein the sensor to detect orbital motion includes a CCD camera.

34. The apparatus of claim 23, wherein the sensor to detect orbital motion includes a laser.

35. The apparatus of claim 23, wherein the sensor to detect orbital motion is a proximity sensor.

36. The apparatus of claim 23, wherein the flexible member is a wire.

37. The apparatus of claim 23, wherein the flexible member is a cable.
